(19) United States
(12) Patent Application Publication
(10) Pub. No.: US 2018/0275172 A1
(43) Pub. Date: Sep. 27, 2018

(54) DEVICE FOR HIGH/MEDIUM/LOW VOLTAGE CURRENT MEASUREMENT

(71) Applicant: ZF Friedrichshafen AG, Friedrichshafen (DE)

(72) Inventors: Thomas ERDMANN, Stemwede (DE); Ajoy PALIT, Bremen (DE)

(73) Assignee: ZF Friedrichshafen AG, Friedrichshafen (DE)

(21) Appl. No.: 15/761,875

(22) PCT Filed: Sep. 6, 2016
(86) PCT No.: PCT/EP2016/070986

§ 371 Date: Mar. 21, 2018

(30) Foreign Application Priority Data
Sep. 23, 2015 (DE) 10 2015 218 290.8

(51) Int. Cl. G01R 15/20; G01R 19/00

(52) U.S. Cl. CPC G01R 15/202; G01R 19/0092

(57) ABSTRACT

The disclosure relates to a device for measuring an electrical current flow comprising a printed circuit board, a sensor component for detecting magnetic fields, said sensor component being arranged on a surface of the printed circuit board, and a conducting element for conducting the current that is to be measured, wherein at least a first portion of the conducting element between a first end of the conducting element and a second end of the conducting element is arranged such that the sensor component is situated between the surface of the printed circuit board and the first portion of the conducting element, such that the sensor component monitors a magnetic field generated by the current flowing through the conducting element.

The disclosure relates to a device for measuring an electrical current flow comprising a printed circuit board, a sensor component for detecting magnetic fields, said sensor component being arranged on a surface of the printed circuit board, and a conducting element for conducting the high/medium/low voltage current that is to be measured.

Such devices are used, for example, for measuring the energy consumption and/or energy transfer from energy suppliers to energy customers. For example, such devices can be used to monitoring current flows in photovoltaic power plants. In some applications, such devices are also used to monitor current flow in order to optimize certain processes, such as for example the charging of a battery.

In the German patent applications DE102011005994A1 and DE19928399A1 examples of devices of this sort are described. In particular, the DE102011005994A1 discloses an arrangement of a sensor package including a printed circuit board with a laminar current conductor arranged on a first main surface of the printed circuit board. The sensor package also includes a sensor chip adapted to measure a current flowing through the laminar current conductor, wherein the sensor chip comprises a magnetic field sensor. The sensor chip is electrically insulated from the current conductor by the printed circuit board, and is arranged on a second main surface of the printed circuit board opposite to the first main surface. The sensor chip is hermetically sealed between the mold material and the printed circuit board, or is arranged in the printed circuit board and hermetically sealed by the printed circuit board.

In the German patent application DE19928399A1 an arrangement of a magnetic field sensor on the surface of a printed circuit board is disclosed, wherein a laminar current conductor is situated underneath the sensor on the surface of the printed circuit board, such that the conductor passes between the contact pins of the sensor.

However, these arrangements are unsuited for use in high voltage applications, high voltage being defined in connection with the disclosure as being greater than 150 Volts, since the laminar current conductors would be destroyed when a high current at high voltage is applied to them. Traditionally, current measurements in high voltage applications are carried out by using shunt resistors or by using transformers. The methods however, can be expensive and cumbersome to implement, as by using shunt resistors overheating due to Ohmic heat losses takes place at high voltage and high current.

The problem for which the disclosure provides a solution is to suggest a device that can directly measure current in high voltage applications in a cost effective manner.

The problem is solved with a device according to claim 1. The dependent claims delineate preferred embodiments of the device.

The problem is therefore solved with a device for measuring an electrical current flow comprising a printed circuit board, a sensor component for detecting magnetic fields, said sensor component being arranged on a surface of the printed circuit board, and a conducting element for conducting the current that is to be measured, wherein at least a first portion of the conducting element between a first end and a second end of the conducting element is arranged such that the sensor component is situated between the surface of the printed circuit board and the conducting element, such that the sensor component monitors a magnetic field generated by the current flowing through the conducting element.

The sensor component, for example a Hall sensor integrated circuit, can be connected to the printed circuit board by means of a number, for example eight, of contact pins. The conducting element is generally a wire, in particular a copper wire, that is embodied for use in high voltage applications.

The conducting element can be electrically connected to the surface of the printed circuit board by being inserted into a through hole or a bored hole in the surface of the printed circuit board and then by being soldered.

Alternatively, the conducting element is connected to the printed circuit board such that at least an insulated distance piece is arranged, in particular two insulated distance pieces are arranged between the surface of the printed circuit board and the conducting element. The conducting element can be positioned just above or as close as possible to the sensitive part of sensor component. The insulated distance piece is a non-conductive spacer which is fixed to the printed circuit board. The insulated distance piece can be inserted through and fixed in bored holes in the printed circuit board.

Since for high voltage applications, the conducting element has a voltage of at least 150 Volts with respect to ground, and the sensor component operates at a considerably lower voltage with respect to ground, for example 3 to 5 Volts, a large electrical potential can exist between the conducting element and the exposed pins of the sensor component. The inventive device enables the measurement of current in such applications wherein the risks, such as spark formation, at such high potentials can be effectively reduced and/or eliminated. The device can monitor DC and/or AC current flows.

In an embodiment of the device, the first portion of the conducting element is at least partially enclosed by an electrical isolating material. Through the use of electrical isolation material, the distance between the sensor component and the first portion of the conducting element can be decreased to the point that only the isolating material separates a surface of the sensor component facing away from the surface of the printed circuit board and the conducting element, which generates a magnetic field when current is flowing. The isolating material, especially in the high voltage application, eliminates the possibility of spark formation in the gap between the first portion of the conducting element and the exposed pins of the sensor component. However, for low (e.g. <12 V) or medium (e.g. <48 V) operational voltage applications the isolating material enclosing the conducting element may not be required. In order to make an accurate measurement of the current flowing in the conducting element, the magnetic field produced by the current must be accurately detected. The term “accurate” in the connection with the disclosure is defined as having an error margin of less than 1%, preferably less than 0.5% and very preferably less than 0.01%. In applications where energy is transferred between an energy provider and a consumer, for example at a charging station for an automobile with an electric drive, the margin of error in the current measurement can have a non-negligible economic impact on the transaction. The magnetic field produced by the conducting element is however generally so small owing to which the earth's magnetic field, or other magnetic fields generated for example by other components in an automobile, can distort in the measurement. Since the strength of the magnetic field generated by the conducting element decreases with an increasing distance from the conducting element, it is advantageous to position the conducting element as close as possible to the sensor component, in order to increase the accuracy of the current measurement. Furthermore, many sensor components that are suitable for use in such applications, such as certain Hall sensor integrated circuits, are designed such that the most sensitive part of the sensor component is located near the surface of the sensor component that faces away from the printed circuit board. For example, one such Hall sensor integrated circuit is most sensitive approximately 0.41 mm below said surface of the Hall sensor integrated circuit.

In an embodiment of the device the sensor component comprises at least two electrical contacts for contacting the printed circuit board and the conducting element is arranged such that a predetermined distance is maintained between the electrical contacts and a second portion of the conducting element that is not enclosed by the isolating material, said distance being in particular predetermined on the basis of a normative regulation offered by an international standards organization. Regulations regarding minimum so called spark gaps that must be maintained in order to ensure the safety of such devices are developed and published by various governmental and nongovernmental certification agencies. For example, the Norm UL1059 from year 2015, published by the Underwriters Laboratories Inc. of Illinois, United States of America, requires that the distance through the air (also known as minimum clearance) between exposed conductors having a potential of at least 301 Volts be at least 9.5 mm and that the minimum distance along a surface (min creepage) is at least 12.7 mm.

In an embodiment of the device the conducting element is arranged such that it comprises at least one loop, in particular an essentially rectangular shaped loop, such that the first portion of the conducting element comprises at least two sections of the conducting element, said sections being arranged parallel to each other. The loop formed by the conducting element served to amplify the magnetic field that can be monitored by the sensor component. In order to achieve this, without introducing distorting magnetic fields, the loop should comprise 1) a first essentially straight section that runs above the sensor component (for SOIC sensor package, for instance), 2) a second essentially straight section that runs perpendicular to the first essentially straight section having a certain length, 3) a third essentially straight section running antiparallel to the first essentially straight section, wherein the distance between the first and third essentially straight sections is determined by the length of the second essentially straight section, and wherein the distance is large enough that a magnetic field generated by current flowing through the third essentially straight section has a magnitude at the location of the sensor component that is small enough so as not distort the measurement of the magnetic field generated by the first essentially straight section, 4) a fourth essentially straight section running antiparallel to the second essentially straight section and 5) a fifth essentially straight section running parallel to the first essentially straight section. The fifth essentially straight section is preferably to be stacked on top of the first essentially straight section with respect to the surface of the sensor component. It is however possible for the first and fifth straight sections to run side by side, with respect to the upper surface of the sensor component. This pattern for the loop can be repeated to form a second loop or even more loops. The advantage of forming such a loop is that the strength of the magnetic field produced by the portion of the conduction element that is arranged close to the surface of the sensor component (i.e. the first and fifth essentially straight sections) that is facing away from the surface of the printed circuit board can be doubled. If the second loop is formed, the magnetic field can be essentially tripled, and so forth. Increasing the strength of the magnetic field increases the accuracy and/or ease of measurement of the current.

In an embodiment the device comprises a magnetically conducting element with a magnetic core, said magnetically conducting element being arranged to at least partially enclose the first portion of the conducting element and serving to magnify the generated magnetic field in the vicinity of the sensor component. The magnetically conducting element should comprise a material having a high relative magnetic permeability, such as at least 100. Ferrite for example can have a relative magnetic permeability of up to 640. The magnetically conducting element can be a “U-Shaped” or “C-shaped” partial cylinder, enclosing three sides of an elongated axis. The magnetically conducting element can be arranged such that the open side with respect to the elongated axis opens towards the sensitive part of sensor component and such that the other three walls of the magnetically conducting element enclose the electrically conducting element. Such an arrangement serves to amplify and concentrate the magnetic field produced by the current flowing through the conducting element permitting an increase in the accuracy and/or ease of measurement of the current.

In an embodiment of the device the conducting element is embodied to conduct voltages between 300 Volts and 600 Volts and is embodied to dissipate heat such that the internal temperature of the conducting element remains below +150 degree Celsius. Sensor components that are available for use in such a device often function with a known temperature dependency. Traditionally, an additional temperature sensor is often required in order to compensate for temperature dependent shifts in measurement accuracy. Through the use of a conducting element, such as a copper wire for example, that is able to conduct large currents at high voltages without overheating, reduces the need for such temperature compensation mechanisms. Furthermore, the fact that the conducting element is separated from the sensor component and that at least the first portion of the conducting element is physically separated from the printed circuit board substrate, has the result that the heat transfer from the conducting element to the sensor component is negligible.

In an embodiment of the device, an additional sensor component is provided, said additional sensor component being arranged a certain distance from the conducting element, wherein the certain distance is large enough that the magnitude of the magnetic field generated by the current flowing in the conducting element is at most 5%, preferably at most 1%, and very preferably at most 0.01%, of the magnitude of the earths' magnetic field at the location of the additional sensor component. The additional sensor component can serve to measure the ambient magnetic field in the vicinity of the device, such as the magnetic field from the earth for example, and the result of this measurement can be subtracted from the measurement of the magnetic field made by the sensor component, that serves to measure the magnetic field generated by the conducting element. The contribution of distorting magnetic fields that are not generated by the conducting element can thereby be eliminated.

The disclosure will next be described in detail with reference to the following figures. The figures show:

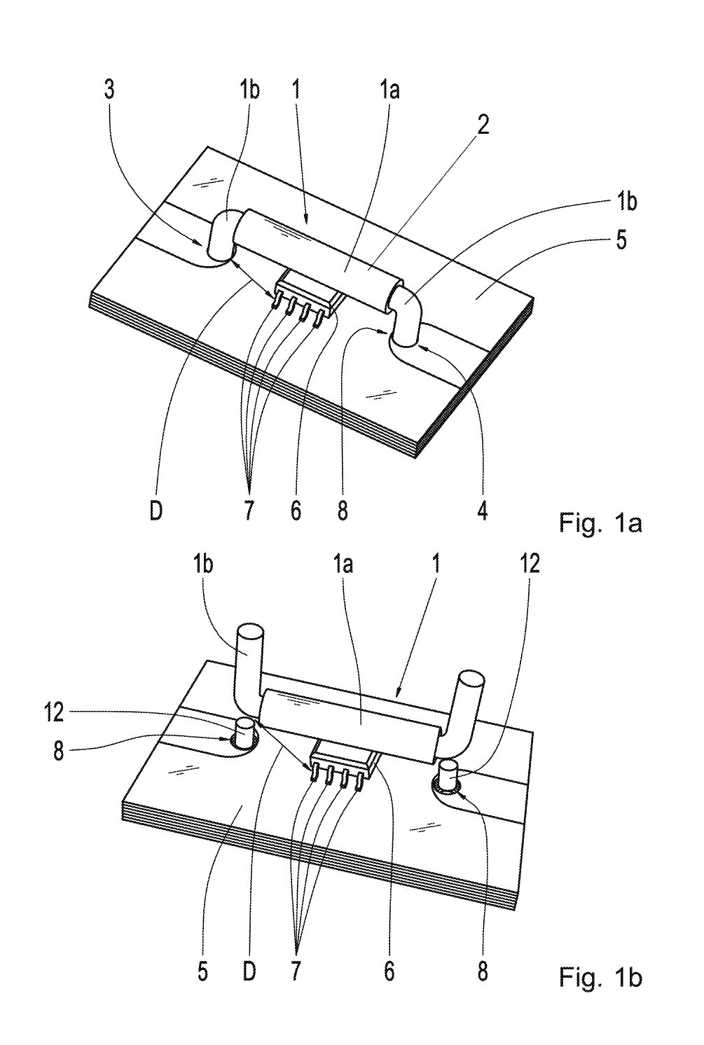

FIG. 1a: a perspective view of a first embodiment of the device for measuring current in a high voltage application

FIG. 1b: a perspective view of a second embodiment of the device for measuring current in a high voltage application

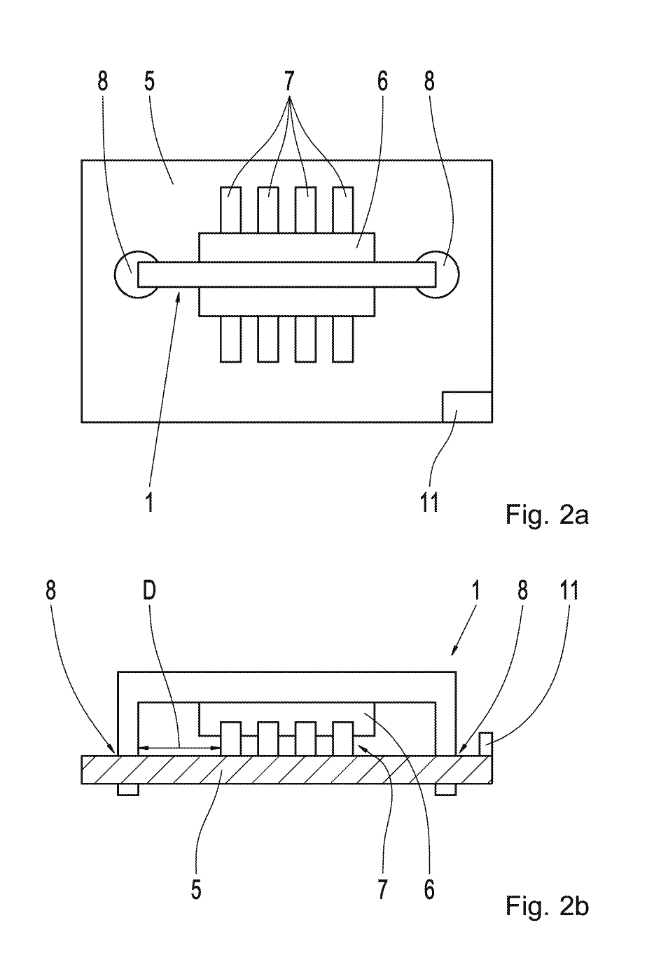

FIG. 2a, 2b: a top view and a side view of an embodiment of the device for measuring current; and

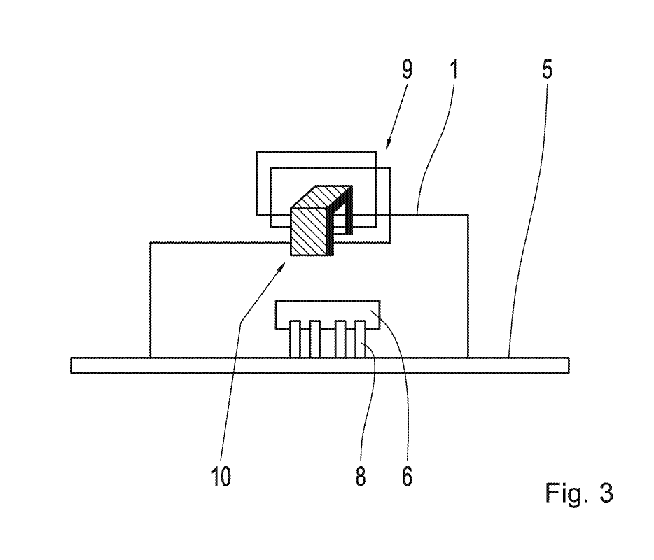

FIG. 3: a schematic perspective view of an embodiment of the device.

FIG. 1a shows a perspective view of a first embodiment of the device for measuring current in a high voltage application. The device can also be used for low or medium-voltage current measurement application in automotive electronics. Shown is a conducting element 1 which is electrically connected to the surface of the printed circuit board 5. An electrically isolating material 2 is enclosing a first portion 1a of the conducting element 1. A second portion 1b of the conducting element 1 is exposed. The second portion 1b makes 90 degree turn at the first end 3 and second end 4 of the conducting element 1 and is soldered on to a printed circuit board 5. A sensor component 6, here a Hall sensor integrated circuit 6 with eight pins 7, is arranged on the printed circuit board 5 between the isolated part 1a of the conducting element 1 and the printed circuit board 5. The conducting element 1 is a copper wire 1, and the first portion 1a of the conducting element 1 is approximately 2 mm thick. Conducting element 1 of thickness 1 mm or less can also be used for other low voltage and low current measurement applications.

FIG. 1b shows an alternative perspective view of a second embodiment of the device for measuring current in a high voltage application. It can also be used for low or medium-voltage current measurement application as mentioned in FIG. 1a. Shown is a conducting element 1 which is not electrically connected to the printed circuit board 5. Between the surface of the printed circuit board 5 and the conducting element 1 an insulated distance pieces 12 is arranged. The insulated distance piece 12 is fixed in a through hole or a bored hole 8 in the printed circuit board 5. The first portion 1a of the conducting element 1 rests and is attached to the insulated distance piece 12. In other words there is no electrical connection between the conducting element 1 and the printed circuit board 5.

The first portion 1a of the conducting element 1 is arranged so that the outer surface of the isolating material 2 is in non-electrical contact with the sensor component 6. The sensor component 6, preferably a Hall sensor integrated circuit is designed to detect magnetic fields. The most sensitive region of the Hall sensor IC 6 is located just below the surface of the Hall sensor IC 6 that is in non-electrical contact with the isolating material 2 enclosing the conducting element 1 and is therefore as close as possible to the source of the magnetic field that is to be measured.

The distance D between the exposed contacts or pins 7 of the sensor component 6 (Hall sensor IC) and the exposed portion 1b of the conducting element 1 fulfills the requirements of the International Norm UL100 from year 2015, published by the Underwriters Laboratories Inc. of Illinois, United States of America, which requires a minimum distance of 5.1 mm between the exposed contacts between which a high voltage difference can occur. In other words the distance D between the exposed contacts or pins 7 of the sensor component 6 and the exposed portion 1b of the conducting element 1 is larger than or equal 5.1 mm.

In FIG. 1b the aforementioned distance D between the exposed contacts 7 and the exposed portion 1b of the conducting element 1 between which distance D a high voltage difference can occur is much larger.

FIG. 2a shows a top view of an embodiment of the device for measuring current. Here, through holes 8 and/or bore holes 8 in the printed circuit board 5 are shown at each of the ends 3, 4 of the conducting element 1. The conducting element 1 is inserted into the holes 8 and soldered onto the printed circuit board 5. FIG. 2 additionally displays an additional sensor component 11 for measuring the ambient magnetic field, for example the earth's magnetic field. This measurement can be used as a control to eliminate any effect this ambient magnetic field might have on the accuracy of the current measurement.

FIG. 2b shows a side view of an embodiment of the device for measuring current that is shown in FIG. 2a.

FIG. 3 shows a schematic perspective view of an embodiment of the device, wherein the conducting element 1 comprises two loops 9 and wherein a magnetically conducting element 10 encloses the electrical conducting element 1 on three sides. Both the loops 9 and the magnetically conducting element 10 serve to amplify the magnetic field produced by the current flowing in the electrical conducting element 1 at the location of the Hall IC 6. The three loops 9 serve to amplify the magnetic field strength by a factor of approximately 3. The magnetically conducting element 10, which is here a c-shaped piece of ferrite material, can serve to amplify the magnetic field by a factor of 100 or more. The effects of the loops 9 and the magnetically conducting element 10 are cumulative.

### REFERENCE SIGNS

1 Conducting element
1a First portion of the conducting element
1b Second portion of the conducting element
2 Isolating material
3 First end of the conducting element
4 Second end of the conducting element
5 Printed circuit board
6 Sensor component/hall sensor IC
7 Pins/leads/contacts of the sensor component
8 Through holes/bore holes
9 Loops
10 Magnetically conducting element
11 Additional sensor component
12 Insulated distance piece
D Distance

1. A device for measuring an electrical current flow comprising:
a printed circuit board,
a sensor component for detecting magnetic fields, said sensor component being arranged on a surface of the printed circuit board, and
a conducting element for conducting the current that is to be measured,
wherein at least a first portion of the conducting element between a first end of the conducting element and a second end of the conducting element is arranged such that the sensor component is situated between the surface of the printed circuit board and the first portion of the conducting element, such that the sensor component is configured to monitor a magnetic field generated by the current flowing through the conducting element.

2. The device according to claim 1, wherein the first portion of the conducting element is at least partially enclosed by an electrical isolating material.

3. The device according to claim 2, wherein the sensor component comprises at least two electrical contacts for contacting the printed circuit board and in that the conducting element is arranged such that a predetermined distance (D) is maintained between the electrical contacts and a second portion of the conducting element that is not enclosed by the isolating material.

4. The device according to claim 1, wherein the conducting element is arranged such that it comprises at least one loop.

5. The device according to claim 1, wherein the device comprises a magnetically conducting element, said magnetically conducting element at least partially enclosing the first portion of the conducting element and configured to magnify the generated magnetic field in the vicinity of the sensor component.

6. The device according to claim 1, wherein the conducting element is configured to conduct voltages between 300 Volts and 600 Volts.

7. The device according to claim 1, wherein an additional sensor component is provided, said additional sensor component being arranged a certain distance from the conducting element, wherein the certain distance is large enough that the magnitude of the magnetic field generated by the current flowing in the conducting element is at most 5% of the magnitude of the earths' magnetic field at the location of the additional sensor component.

8. The device according to claim 1, wherein the conducting element is electrically connected to the printed circuit board such that the first end of the conducting element and the second end of the conducting element are electrically connected to the surface of the printed circuit board.

9. The device according to claim 1, further comprising an insulated distance piece, wherein the conducting element is connected to the printed circuit board such that the insulated distance piece is arranged between the surface of the printed circuit board and the conducting element.

10. The device according to claim 3, wherein the distance (D) is predetermined on the basis of a normative regulation offered by an international standards organization.

11. The device according to claim 3, wherein the distance is larger or equal to 5.1 mm.

12. The device according to claim 4, wherein the at least one loop is a rectangular shaped loop, such that the first portion of the conducting element comprises at least two sections of the conducting element, wherein the at least two sections being arranged parallel to each other.

13. The device according to claim 6, wherein the conducting element is configured to dissipate heat such that the internal temperature of the conducting element remains below 150 degree of Celsius.

14. The device according to claim 1, wherein an additional sensor component is provided, said additional sensor component being arranged a certain distance from the conducting element, wherein the certain distance is large enough that the magnitude of the magnetic field generated by the current flowing in the conducting element is at most 0.01% of the magnitude of the earths' magnetic field at the location of the additional sensor component.

15. The device according to claim 2, wherein an outer surface of the electrical isolating material is in non-electrical contact with the sensor component.

16. The device according to claim 9, wherein the first portion of the conducting element is attached to the insulated distance piece.

17. The device according to claim 4, wherein the at least one loop comprises a first essentially straight section that runs above the sensor component, a second essentially straight section that runs perpendicular to the first essentially straight section, a third essentially straight section running antiparallel to the first essentially straight section, a fourth essentially straight section running antiparallel to the second essentially straight section, and a fifth essentially straight section running parallel to the first essentially straight section;
wherein a distance between the first and third essentially straight sections is determined by a length of the second essentially straight section, and wherein the distance is large enough that a magnetic field generated by current flowing through the third essentially straight section has a magnitude at the location of the sensor component that is small enough so as not distort the measurement of the magnetic field generated by the first essentially straight section.

18. The device according to claim 17, wherein the first and fifth essentially straight sections to run side by side.

19. The device according to claim 17, wherein the fifth essentially straight section is stacked on top of the first essentially straight section with respect to the surface of the sensor component.

20. The device according to claim 17, further comprising a second loop, wherein the second loop comprises the fifth essentially straight section, a sixth essentially straight section that runs perpendicular to the fifth essentially straight section, a seventh essentially straight section running antiparallel to the fifth essentially straight section, an eighth essentially straight section running antiparallel to the sixth essentially straight section, and a ninth essentially straight section running parallel to the fifth essentially straight section;
wherein a distance between the fifth and seventh essentially straight sections is determined by a length of the sixth essentially straight section, and wherein the distance is large enough that a magnetic field generated by current flowing through the seventh essentially straight section has a magnitude at the location of the sensor component that is small enough so as not distort the measurement of the magnetic field generated by the fifth essentially straight section.
